(19) United States
(12) Patent Application Publication
(10) Pub. No.: US 2026/0188158 A1
(43) Pub. Date: Jul. 2, 2026

(54) Display Apparatus

(71) Applicant: LG Display Co., Ltd., Seoul (KR)

(72) Inventors: Goeun Kim, Seoul (KR); SeWan Oh, Seoul (KR)

(21) Appl. No.: 19/411,002

(22) Filed: Dec. 5, 2025

(30) Foreign Application Priority Data
Dec. 31, 2024 (KR) 10-2024-0202245

(51) Int. Cl. G09G 3/02; G09G 3/3233

(52) U.S. Cl. CPC G09G 3/025; G09G 3/3233; G09G 2300/0452; G09G 2300/0804; G09G 2320/0233; G09G 2320/028; G09G 2354/00; G09G 2358/00; G09G 2380/10

(57) ABSTRACT

A display apparatus presented herein includes a substrate, a first light emitting diode and a second light emitting diode disposed on the substrate and emitting light of the same color, and a lens disposed on the first light emitting diode and the second light emitting diode. The lens controls a path of light emitted from the first light emitting diode and the second light emitting diode. Both side surfaces of the lens have curvature, and a top surface of the lens is flat.

### CROSS-REFERENCE TO RELATED APPLICATION

The present application claims the priority to Republic of Korea Patent Application No. 10-2024-0202245, filed on December 31, 2024, which is incorporated herein by reference in its entirety.

### BACKGROUND

### Field

The present disclosure relates to a display apparatus, and more particularly, to a display apparatus for controlling an optical path.

### Description of the Related Art

As modern technology advances, various types of display devices such as a liquid crystal display (LCD) device and an organic light emitting display (OLED) device have been developed.

Display devices are widely utilized in TVs and computer monitors, and recently have also been increasingly employed as user interfaces of portable display devices and other electronic devices. In particular, as IT technology advances, display devices are also adopted as vehicle instrument panels.

In general, display devices have no limitation in viewing angle. However, for example, in the case of a display device for providing driving information and content for vehicles, the limitation of the viewing angle may vary depending on whether the driver is driving and whether the driver or a passenger in the front passenger seat is viewing. Accordingly, it is necessary to selectively set the viewing angle for images displayed on the display device.

### SUMMARY

An object to be achieved by the present disclosure is to provide a display apparatus capable of controlling an optical path in a plurality of main viewing directions through a single lens.

An object to be achieved by the present disclosure is to provide a display apparatus that may improve luminance in each of the plurality of main viewing directions.

Objects of the present disclosure are not limited to the above-mentioned objects, and other objects, which are not mentioned above, can be clearly understood by those skilled in the art from the following descriptions.

According to one or more embodiments of the present disclosure, there is provided a display apparatus. The display apparatus includes a substrate. The display apparatus further includes a first light emitting diode and a second light emitting diode disposed on the substrate and emitting light of the same color. And the display apparatus further includes a lens disposed on the first light emitting diode and the second light emitting diode and controlling a path of light emitted from the first light emitting diode and the second light emitting diode. Both side surfaces of the lens have curvature, and a top surface of the lens is flat.

According to one or more embodiments of the present disclosure, there is provided a display apparatus. The display apparatus includes a substrate in which a plurality of pixels each including a plurality of sub pixels is defined. The display apparatus further includes a first light emitting diode and a second light emitting diode disposed on the substrate in each of the plurality of sub pixels. And the display apparatus further includes a a lens disposed on the first light emitting diode and the second light emitting diode in each of the plurality of sub pixels, the lens controlling a path of light emitted from the first light emitting diode in a first direction, and the lens controlling a path of light emitted from the second light emitting diode in a second direction different from the first direction. A top surface of the lens is flat, and both side surfaces of the lens are curved surfaces.

According to one or more embodiments of the present disclosure, there is provided a display apparatus. The display apparatus includes a substrate, a first light emitting diode and a second light emitting diode disposed on the substrate, wherein the first light emitting diode and the second light emitting diode are adjacent to each other and are configured to emit light of a same color, and a lens at least partially overlapping the first light emitting diode and the second light emitting diode. The lens includes a bottom surface and a top surface opposite to the bottom surface and further from the substrate than the bottom surface, wherein at least a portion of the top surface is flat. A luminance of the light emitted from the first light emitting diode and the second light emitting diode and transmitted through the lens at a zero viewing angle is less than a luminance of the light emitted from the first light emitting diode and the second light emitting diode and transmitted through the lens at non-zero viewing angles. The lens further includes a pair of side surfaces, wherein at least a portion of a first side surface of the pair of side surfaces is curved.

Other detailed matters of the embodiments are included in the detailed description and the drawings.

According to the present disclosure, one lens and a plurality of light emitting diodes may be matched in each sub pixel to implement light directivity toward different main viewing directions.

According to the present disclosure, by means of a lens having a flat top surface, freedom in lens height may be secured and the side surface of the lens may be implemented with low curvature, thereby providing high-luminance images for each of the different main viewing directions.

The effects according to the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings.

FIG. 1 is an example of a display apparatus according to one or more embodiments of the present disclosure.

FIG. 2 is a block diagram of a display apparatus according to one or more embodiments of the present disclosure.

FIG. 3 is a schematic cross-sectional view of a display apparatus according to one or more embodiments of the present disclosure.

FIG. 4 is an enlarged cross-sectional view of a sub pixel area of a display apparatus according to one or more embodiments of the present disclosure.

FIG. 5 is a cross-sectional view illustrating a first example of a lens of a display apparatus according to one or more embodiments of the present disclosure.

FIG. 6 is a cross-sectional view illustrating a second example of a lens of a display apparatus according to one or more embodiments of the present disclosure.

FIG. 7 is a cross-sectional view illustrating a structure of a lens according to a first comparative example.

FIG. 8 is a cross-sectional view illustrating a structure of a lens according to a second comparative example.

FIG. 9 is a diagram comparing luminance profiles of the first example and the second example of a lens of a display apparatus according to one or more embodiments of the present disclosure with luminance profiles according to the first comparative example.

FIG. 10 is a diagram comparing a luminance profile of a third example of a lens of a display apparatus according to one or more embodiments of the present disclosure with luminance profiles according to the first comparative example and the second comparative example.

FIG. 11A is a diagram illustrating luminance profiles in two main viewing directions through a lens of a display apparatus according to one or more embodiments of the present disclosure.

FIG. 11B is a diagram illustrating luminance profiles in two main viewing directions through a lens according to the first comparative example.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

In the presentdisclosure, a “display apparatus” may include a display apparatus which includes a display panel and a driver for driving the display panel, in a narrow sense, such as a liquid crystal module (LCM), an organic light emitting module (OLED module), and a quantum dot module. Further, the “display apparatus” may further include a set electronic apparatus or a set apparatus (or a set device) which is a complete product or a final product including an LCM, an OLED module, a QD module, etc., such as a notebook computer, a television, or a computer monitor, an automotive display apparatus or equipment display apparatus including another type of vehicle and a mobile electronic apparatus including a smart phone or an electronic pad. Accordingly, the display apparatus of the present disclosure may include not only a display apparatus itself in a narrow sense such as an LCM, an OLED module, a QD module, etc., but also an applied product or a set apparatus which is a final consumer device including the LCD, the OLED module, the QD module, etc.

Further, in some cases, the LCM, the OLED module, or the QD module which is configured by a display panel and a driver may be represented as “a display apparatus” in a narrow sense and an electronic device as a complete product including the LCM, the OLED module, and the QD module may be represented as a “set apparatus”. For example, the display apparatus in the narrow sense includes a liquid crystal (LCD) display panel, an OLED display panel, or a quantum dot display panel and a source PCB which is a controller for driving the display panel. In contrast, the set apparatus may be a concept further including a set PCB which is a set controller which is electrically connected to the source PCB to control the entire set apparatus.

As a display panel used in one or more embodiments of the present disclosure, any type of display panel such as a liquid crystal display panel, an organic light emitting diode (OLED) display panel, a quantum dot (QD) display panel, and an electroluminescent display panel may be used. The display panel of the one or more embodiments is not limited to a specific display panel in which a bezel is bent with a flexible substrate for the organic light emitting diode (OLED) display panel and a back plate support structure therebelow. Further, a display panel used for the display apparatus according to one or more embodiments of the present disclosure is not limited to a shape or a size of the display panel.

For example, when the display panel is an OLED display panel, the display panel may include a plurality of gate lines, data lines, and pixels formed at intersecting areas of the gate lines and/or data lines. Further, the display panel may be configured to include an array including a thin film transistor which is an element to selectively apply a voltage to each pixel, a light emitting diode layer on the array, an encapsulation substrate or an encapsulation layer, and the like disposed on the array so as to cover the light emitting diode layer. The encapsulation layer may protect the thin film transistor the light emitting diode layer, and the like from external impacts and may suppress the permeation of moisture or oxygen into the light emitting diode layer. Further, a layer formed on the array may include an inorganic light emitting layer, for example, a nano-sized material layer quantum dots, or the like.

The features of various embodiments of the present disclosure can be partially or entirely adhered to or combined with each other and can be interlocked and operated in technically various ways, and the embodiments can be carried out independently of or in association with each other.

Hereinafter, a display apparatus according to embodiments of the present disclosure will be described in detail with reference to accompanying drawings.

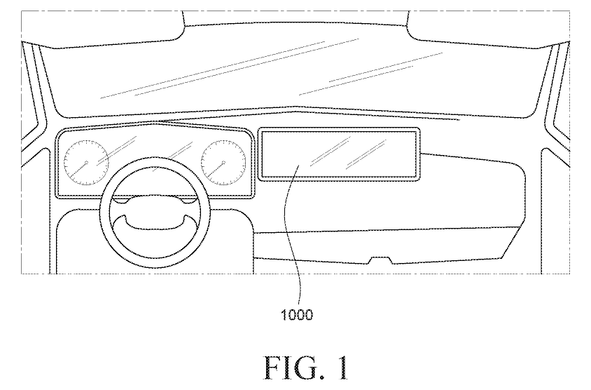

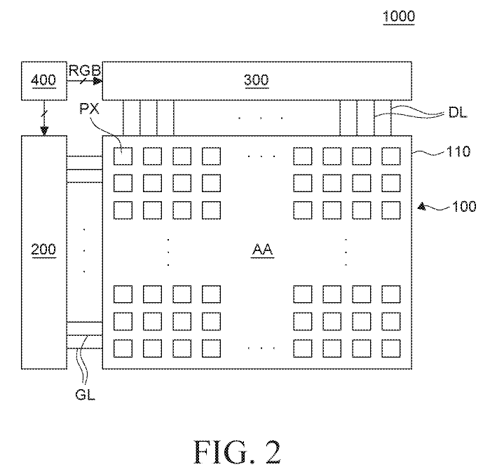

FIG. 1 is an example of a display apparatus according to one or more embodiments of the present disclosure. FIG. 2 is a block diagram of a display apparatus according to one or more embodiments of the present disclosure.

Referring to FIG. 1, a display apparatus 1000 according to one or more embodiments of the present disclosure may be a vehicle display apparatus, but is not limited thereto.

Hereinafter, as illustrated in FIG. 1, description will be made on the display apparatus 1000 according to one or more embodiments of the present disclosure being disposed on a dashboard and a center fascia between a driver at a driver’s seat and a passenger at an assistant seat in a vehicle, but is not limited thereto. In addition, hereinafter, the left side of the display apparatus 1000 is described as a first viewing direction facing the driver’s seat, and the right side as a second viewing direction facing the assistant seat, but the main viewing direction of a viewer watching an image displayed on the display apparatus 1000 is not limited thereto.

Referring to FIG. 2, the display apparatus 1000 may include a display panel 100, a gate driving circuit 200, a data driving circuit 300, and a timing controller 400.

The display panel 100 may display an image to be provided to a user through a plurality of pixels PX disposed in an active area AA on a substrate 110.

The gate driving circuit 200, the data driving circuit 300, and the timing controller 400 may provide signals for the operation of each pixel PX through signal lines. For example, the signal lines may include data lines DL and gate lines GL.

The display apparatus 1000 may further include a power supply unit. In this case, signals for operating pixel PX may be provided through power lines connecting the power supply unit and the display panel 100.

The power supply unit may provide power to the data driving circuit 300 and the gate driving circuit 200. The data driving circuit 300 and the gate driving circuit 200 may be driven based on the power provided from the power supply unit. For example, the data driving circuit 300 may apply a data signal to each pixel PX through the data lines DL, the gate driving circuit 200 may apply a gate signal to each pixel PX through the gate lines GL, and the power supply unit may supply a power voltage to each pixel PX through power voltage supply lines.

The timing controller 400 may control the data driving circuit 300 and the gate driving circuit 200. For example, the timing controller 400 may rearrange digital video data input from the outside in accordance with the resolution of the display panel 100 and supply it to the data driving circuit 300.

The gate driving circuit 200 may generate a scan signal and a light emitting signal (or a light emitting control signal) based on a gate control signal. The gate driving circuit 200 may include a scan driver and a light emitting signal driver. The scan driver may generate a scan signal in a row-sequential manner to drive at least one gate line GL connected to each pixel row, and supply the scan signal to the gate lines GL. The light emitting signal driver may generate a light emitting signal in a row-sequential manner to drive at least one light emitting signal line connected to each pixel row, and supply the light emitting signal to the light emitting signal lines.

For example, the gate driving circuit 200 may be disposed on the display panel 100 in a gate-driver in panel (GIP) method. For example, the gate driving circuit 200 may be divided into a plurality of portions and disposed on at least two sides of the display panel 100, respectively.

The data driving circuit 300 may convert digital video data RGB input from the timing controller 400 into an analog data voltage based on a data control signal, and supply the analog data voltage to a plurality of data lines DL.

Each of the gate driving circuit 200 and the data driving circuit 300 may be implemented as one or more integrated circuits, and in view of electrical connection with the display panel 100, may be implemented as a chip on glass (COG) type, chip on film (COF) type, or tape carrier package (TCP) type.

On the substrate 110 of the display panel 100, a plurality of pixels PX may be disposed in the active area AA. On the substrate 110, a plurality of data lines DL and a plurality of gate lines GL may intersect each other, and sub pixels configuring each pixel PX may be disposed at the intersection areas. One pixel PX may include a plurality of sub pixels emitting different colors. For example, one pixel PX may include a first sub pixel emitting red, a second sub pixel emitting green, and a third sub pixel emitting blue, but is not limited thereto. For example, one pixel PX may further include a sub pixel for implementing a specific color (e.g., white) in addition to red, green, and blue. The area implementing blue in a pixel PX may be referred to as a blue sub pixel area, the area implementing red as a red sub pixel area, and the area implementing green as a green sub pixel area.

The substrate 110 of the display panel 100 may further include a non-active area around the active area AA, and the non-active area may be disposed along the periphery of the active area AA. Various components for driving a pixel driving circuit disposed together with pixels PX may be disposed in the non-active area. For example, at least a portion of the gate driving circuit 200 may be disposed in the non-active area. The non-active area may be referred to as a bezel area.

Each of the plurality of sub pixels may include a light emitting diode and a pixel driving circuit for controlling an amount of current flowing in the light emitting diode.

In one or more embodiments of the present disclosure, description is made on the assumption that the display apparatus 1000 is an organic light emitting display apparatus, but the embodiments of the present disclosure are not limited thereto. For example, when the display apparatus 1000 is an organic light emitting display apparatus, the sub pixel may include a light emitting diode including an anode electrode, an organic emission layer on the anode electrode, and a cathode electrode on the organic emission layer. The light emitting diode may further include a hole transport layer, a hole injection layer, an electron injection layer, and an electron transport layer, in addition to the organic emission layer.

The pixel driving circuit may include a plurality of thin film transistors (TFTs). For example, the pixel driving circuit may include a switching transistor, a driving transistor, and a capacitor. In addition, the pixel driving circuit may include a high potential power line and a low potential power line as wiring lines connected to a power supply for driving the sub pixel.

In this case, the light emitting diode may operate to emit light according to a driving current formed by the driving transistor. The switching transistor may perform a switching operation such that a data signal supplied through data line DL is stored as a data voltage in the capacitor in response to a scan signal supplied through gate line GL. The driving transistor may operate such that a constant driving current flows between the high potential power line and the low potential power line in response to the data voltage stored in the capacitor.

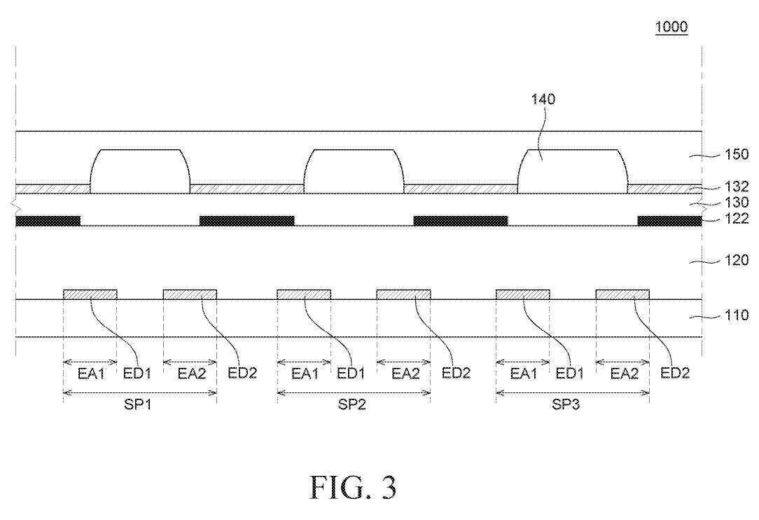

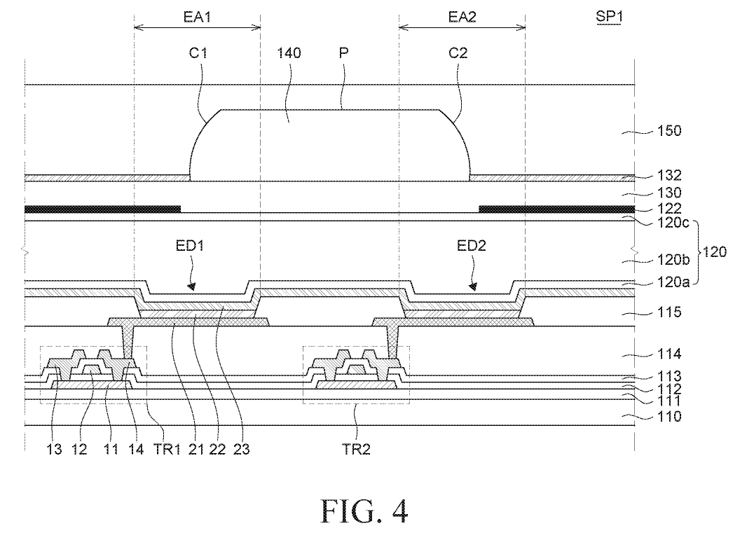

Hereinafter, referring to FIGS. 3 and 4, the structure of the display apparatus 1000 according to one or more embodiments of the present disclosure will be described in more detail.

FIG. 3 is a schematic cross-sectional view of a display apparatus according to one or more embodiments of the present disclosure. FIG. 4 is an enlarged cross-sectional view of a sub pixel area of a display apparatus according to one or more embodiments of the present disclosure.

In FIG. 3, a cross-section of one pixel PX is illustrated as an example, the one pixel PX including a first sub pixel SP1 having a first light emitting diode ED1 and a second light emitting diode ED2 each emitting light of the same color (e.g., red), a second sub pixel SP2 having a first light emitting diode ED1 and a second light emitting diode ED2 each emitting light of the same color (e.g., green), and a third sub pixel SP3 having a first light emitting diode ED1 and a second light emitting diode ED2 each emitting light of the same color (e.g., blue). The first light emitting diode ED1 and the second light emitting diode ED2 may be adjacent to each other.

In addition, in FIG. 4, an enlarged cross-section of a sub pixel area in which one sub pixel (e.g., first sub pixel SP1) is disposed is illustrated as an example.

Referring to FIGS. 3 and 4 together, the display apparatus 1000 includes a substrate 110 of a display panel 100, a buffer layer 111 disposed on the substrate 110, a first thin film transistor TR1 and a second thin film transistor TR2 disposed on the buffer layer 111, a gate insulating layer 112 disposed on the buffer layer 111, an interlayer insulating layer 113 disposed on the gate insulating layer 112, a planarization layer 114 disposed on the interlayer insulating layer 113, a first light emitting diode ED1 and a second light emitting diode ED2 disposed on the planarization layer 114, and a bank 115 disposed on the planarization layer 114 and defining the emission areas of the first light emitting diode ED1 and the second light emitting diode ED2.

The substrate 110 may be formed of a rigid material such as glass, or may be formed of a plastic-based material such as polyimide, but is not limited thereto.

The buffer layer 111 may be formed over the entire substrate 110. The buffer layer 111 may enhance adhesion between the substrate 110 and layers formed on the buffer layer 111. The buffer layer 111 may serve to block various types of defect substances such as alkali components emitted from the substrate 110, and may serve to suppress diffusion of moisture or oxygen permeated into the substrate 110. The buffer layer 111 may be formed of a single layer of SiNx or SiOx, or a multilayer thereof, but is not limited thereto. In addition, the buffer layer 111 may be omitted depending on the type and material of the substrate 110, or the structure and type of thin film transistor disposed above.

On the buffer layer 111, the first thin film transistor TR1 electrically connected to the first light emitting diode ED1, and the second thin film transistor TR2 electrically connected to the second light emitting diode ED2 are disposed.

Each of the first thin film transistor TR1 and the second thin film transistor TR2 is disposed on the buffer layer 111 and includes a semiconductor pattern 11 including a channel region at the center and source and drain regions which are doped layers at both sides of the channel region, a gate electrode 12 disposed on the gate insulating layer 112 covering the semiconductor pattern 11 so as to overlap the semiconductor pattern 11, and a source electrode 13 and a drain electrode 14 disposed on the interlayer insulating layer 113 covering the gate electrode 12 and electrically connected to semiconductor pattern 11. The source electrode 13 and the drain electrode 14 may be in contact with source and drain regions of semiconductor pattern 11 through contact holes formed in the gate insulating layer 112 and the interlayer insulating layer 113.

For example, the semiconductor pattern 11 may be formed of an oxide semiconductor such as indium-gallium-zinc-oxide (IGZO), indium-zinc-oxide (IZO), indium-gallium-tin-oxide (IGTO), indium-gallium-oxide (IGO), and the like, but is not limited thereto. As another example, the semiconductor pattern 11 may be formed of a polycrystalline semiconductor composed of low temperature poly silicon (LTPS) having high mobility, but is not limited thereto.

The gate insulating layer 112 may be configured as a single layer or a plurality of layers formed of an inorganic material such as SiOx or SiNx, but is not limited thereto.

The interlayer insulating layer 113 may be formed of at least one of an organic material such as photo acryl, and an inorganic material such as SiNx or SiOx, and may be configured as a single layer or a plurality of layers thereof, but is not limited thereto.

The gate electrode 12, the source electrode 13, and the drain electrode 14 may each be formed of a metal such as molybdenum (Mo), aluminum (Al), chromium (Cr), gold (Au), titanium (Ti), nickel (Ni), neodymium (Nd), and copper (Cu), and may be configured as a single layer or a plurality of layers formed of any one of these metals or an alloy thereof, but is not limited thereto.

The planarization layer 114 is disposed on the first thin film transistor TR1, the second thin film transistor TR2, and the interlayer insulating layer 113.

The planarization layer 114 may be formed of an organic material such as photo acryl, but is not limited thereto. For example, the planarization layer 114 may be configured as a plurality of layers composed of an inorganic layer and an organic layer.

On the planarization layer 114 in each sub pixel area, the first light emitting diode ED1 and the second light emitting diode ED2 emitting light of the same color are disposed.

Each of the first light emitting diode ED1 and the second light emitting diode ED2 includes a first electrode 21 electrically connected to the first thin film transistor TR1 and the second thin film transistor TR2 through a contact hole formed in the planarization layer 114, an emission layer 22 disposed on the first electrode 21, and a second electrode 23 disposed on the emission layer 22.

The first electrode 21 may be formed of at least one of silver (Ag), aluminum (Al), gold (Au), molybdenum (Mo), tungsten (W), chromium (Cr), ytterbium (Yb), or an alloy thereof, but is not limited thereto. In addition, the first electrode 21 may be formed as a transparent metal oxide layer such as indium tin oxide (ITO) or indium zinc oxide (IZO), and may further include an opaque conductive material to serve as a reflective electrode reflecting the light.

The emission layer 22 is disposed on the first electrode 21. The emission layer 22 is disposed on the first electrode 21 exposed through an opening defined by the bank 115. In FIG. 4, the emission layer 22 disposed inside the opening defined by the bank 115 is described as an example, but is not limited thereto. For example, the emission layer 22 may extend and be disposed to at least a portion of the side surface and top surface of the opening.

The emission layer 22 may include at least one of a red emission layer emitting red light, a green emission layer emitting green light, and a blue emission layer emitting blue light, but is not limited thereto. For example, the emission layer 22 may further include a white emission layer emitting white light.

The emission layer 22 may include an organic emission layer. The emission layer 22 may further include, in addition to the organic emission layer, an electron injection layer and a hole injection layer that respectively inject electrons and holes into the organic emission layer, an electron transport layer and a hole transport layer that respectively transport the injected electrons and holes into the emission layer, a hole blocking layer, an electron blocking layer, and a hole transport layer, but is not limited thereto. In addition, the emission layer 22 may include an inorganic emission layer such as a nano-sized material layer, a quantum dot, a micro LED emission layer, or a mini LED emission layer, but is not limited thereto.

The second electrode 23 is disposed on the emission layer 22. The second electrode 23 may be formed over an entire plurality of sub pixels SP1, SP2, and SP3.

For example, the second electrode 23 may be formed of a semitransparent conductive material transmitting light. The second electrode 23 may be formed of at least one of alloys such as LiF/Al, CsF/Al, Mg:Ag, Ca/Ag, Ca:Ag, LiF/Mg:Ag, LiF/Ca/Ag, or LiF/Ca:Ag, but is not limited thereto. The second electrode 23 may be composed of a transparent metal oxide such as indium tin oxide (ITO) or indium zinc oxide (IZO), but is not limited thereto.

In addition, the display apparatus 1000 further includes an encapsulation layer 120 covering the plurality of sub pixels SP1, SP2, and SP3, a first barrier layer 122 disposed on the encapsulation layer 120, an organic insulating layer 130 disposed on the encapsulation layer 120 and the first barrier layer 122, a second barrier layer 132 disposed on the organic insulating layer 130, a plurality of lenses 140, and a lens protection layer 150 covering the second barrier layer 132 and the plurality of lenses 140.

The encapsulation layer 120 is disposed on the first light emitting diode ED1 and the second light emitting diode ED2 and covering the first light emitting diode ED1 and the second light emitting diode ED2, to protect the first light emitting diode ED1 and the second light emitting diode ED2 from being exposed to impurities such as moisture or oxygen.

For example, as illustrated in FIG. 4, the encapsulation layer 120 may be configured as a plurality of layers including a first encapsulation layer 120a, a second encapsulation layer 120b, and a third encapsulation layer 120c, but is not limited thereto. The first encapsulation layer 120a and the third encapsulation layer 120c may be formed of an inorganic material such as SiOx or SiNx, but are not limited thereto. The second encapsulation layer 120b may be formed of an organic insulating material such as acrylic resin, epoxy resin, polyimide, polyethylene, or silicon oxycarbide (SiOC), but is not limited thereto.

The first barrier layer 122 is disposed on the encapsulation layer 120 and is disposed so as to enclose a lens 140 on a plane. The first barrier layer 122 may be disposed closer to the substrate 110 than the lens 140 is disposed. In one embodiment, the lens 140 may have a shape that is modified from or similar to a semi-cylindrical or spherical form. For example, in plan view, the lens 140 may have a bar shape or a spherical shape, and in cross section, the lens 140 may include a curved portion close to a semicircular shape. In this case, side surfaces of the lens 140 facing each other may have a curvature profile. That is, the lens 140 may be substantially semi-cylindrical or hemispherical in shape to control a path of emitted light, but the shape of the lens 140 is not limited thereto. The lens 140 may control a path of light emitted from the first light emitting diode ED1 in a first direction, and may control a path of light emitted from the second light emitting diode ED2 in a second direction different from the first direction. The first barrier layer 122 may suppress light emitted from the first light emitting diode ED1 and light emitted from the second light emitting diode ED2 from being color-mixed with each other.

The first barrier layer 122 may overlap a portion of the emission area EA1 of the first light emitting diode ED1 and a portion of the emission area EA2 of the second light emitting diode ED2, but is not limited thereto. For example, the first barrier layer 122 may be non-overlapping with emission area EA1 of the first light emitting diode ED1 and emission area EA2 of the second light emitting diode ED2. Further, a portion of the first barrier layer 122 may overlap a portion of the emission layer 22 of the first light emitting diode ED1 that does not overlap the lens 140, and another portion of the first barrier layer 122 may overlap a portion of the emission layer 22 of the second light emitting diode ED2 that does not overlap the lens 140.

For example, the first barrier layer 122 may include a light absorbing material, or may be a layer on which a light absorbent is coated, and may be a black matrix including a carbon-based black pigment, but is not limited thereto. The first barrier layer 122 may absorbs a portion of the light emitted from the first light emitting diode ED1 and light emitted from the second light emitting diode ED2.

The organic insulating layer 130 is disposed on the first barrier layer 122 and the encapsulation layer 120. For example, the organic insulating layer 130 may be an optical gap layer for securing an optical distance between the light emitting diode and lens so that light emitted from the light emitting diode may be refracted in a specific direction by the lens. The organic insulating layer 130 may have a thickness of several to several tens of μm, but the thickness is not limited thereto. For example, the organic insulating layer 130 may include an organic insulating material such as photo acryl, benzocyclobutene (BCB), polyimide (PI), or polyamide (PA), but the material is not limited thereto.

A plurality of lenses 140 is disposed on the organic insulating layer 130 and controls the optical path of light emitted from each of the first light emitting diode ED1 and the second light emitting diode ED2. Referring to FIG. 4, each of the plurality of lenses 140 includes a bottom surface and a top surface P opposite to the bottom surface and further from the substrate 110 than the bottom surface. At least a portion of the top surface P is flat. Each of the plurality of lenses 140 further includes a pair of side surfaces C1 and C2. At least a portion of the side surface C1 and/or the side surface C2 may be curved and have curvature. The side surfaces C1 and C2 may be curved surfaces facing each other. The bank 115 disposed between the first light emitting diode ED1 and the second light emitting diode ED2 may overlap the top surface P of the lens 140.

Each of the plurality of lenses 140 is disposed on one sub pixel, and accordingly, one lens 140 is matched with two light emitting diodes, i.e., the first light emitting diode ED1 and the second light emitting diode ED2. The lens 140 at least partially overlaps the first light emitting diode ED1 and the second light emitting diode ED2. In this case, in one sub pixel, a portion of the flat top surface of lens 140 and one of the both side surfaces overlap with the first light emitting diode ED1, and another portion of the flat top surface of lens 140 and the other of the both side surfaces overlap with the second light emitting diode ED2. Specifically, the emission layer 22 of the first light emitting diode ED1 may be disposed in an opening defined by the bank 115, with the side surface C1 and a portion of the top surface P of the lens 140 overlapping a portion of the emission layer 22 of the first light emitting diode ED1. Further, the emission layer 22 of the second light emitting diode ED2 may be disposed in another opening defined by the bank 115, with the side surface C2 and another portion of the top surface P of the lens 140 overlapping a portion of the second emission layer 22 of the second light emitting diode ED2.

The second barrier layer 132 is disposed on the organic insulating layer 130 on the same plane as the lens 140 and is disposed so as to enclose the lens 140 on a plane. The second barrier layer 132 may be in direct contact with the side surfaces C1 and C2 of the lens 140. The second barrier layer 132 may overlap with the first barrier layer 122, and may be diposed further from the substrate 110 than the first barrier layer 122is disposed. The second barrier layer 132 may include a light absorbing material for absorbing a portion of light emitted from the emission layer 22 of the first light emitting diode ED1 and the second light emitting diode ED2. By means of the second barrier layer 132, the viewing angle of light emitted from emission area EA1 of the first light emitting diode ED1 and emission area EA2 of the second light emitting diode ED2 may be limited such that the light may be emitted with a specific angle.

The second barrier layer 132 may overlap a portion of the emission area EA1 of the first light emitting diode ED1 and a portion of the emission area EA2 of the second light emitting diode ED2, but is not limited thereto. For example, the second barrier layer 132 may be non-overlapping with the emission area EA1 of the first light emitting diode ED1 and the emission area EA2 of the second light emitting diode ED2. In addition, the size where the second barrier layer 132 overlaps with the emission area EA1 of the first light emitting diode ED1 and the emission area EA2 of the second light emitting diode ED2 may be larger than the size where the first barrier layer 122 overlaps with the emission area EA1 of the first light emitting diode ED1 and the emission area EA2 of the second light emitting diode ED2, but is not limited thereto. For example, the size where the second barrier layer 132 overlaps with the emission area EA1 of the first light emitting diode ED1 and the emission area EA2 of the second light emitting diode ED2 may be the same as the size where the first barrier layer 122 overlaps with the emission area EA1 of the first light emitting diode ED1 and the emission area EA2 of the second light emitting diode ED2. Specifcially, a portion of the second barrier layer 132 in direct contact with the side surface C1 of the lens 140 overlaps a portion of the first barrier layer 122 that overlaps with the emission layer 22 of the first light emitting diode ED1, and another portion of the second barrier layer 132 in direct contact with the side surface C2 of the lens 140 overlaps another portion of the first barrier layer 122 that overlaps with the emission layer 22 of the second light emitting diode ED2. As shown in FIG. 4, an overlapping area of the second barrier layer 132 overlapping with the portion of the emission area EA1 of the first light emitting diode ED1 and the emission area EA2 of the second light emitting diode ED2 may be wider than an overlapping area of the first barrier layer 122 overlapping with the portion of the emission area EA1 of the first light emitting diode ED1 and the emission area EA2 of the second light emitting diode ED2.

As the first barrier layer 122 and the second barrier layer 132 overlap with a portion of the emission area EA1 and a portion of the emission area EA2, light emitted from the first light emitting diode ED1 and the second light emitting diode ED2 may be efficiently suppressed from being incident on an adjacent lens 140. Accordingly, even without reducing the emission areas of the first light emitting diode ED1 and the second light emitting diode ED2, light separation into a plurality of main viewing directions may be achieved, thereby suppressing a decrease in luminance. In a case where the viewing angle when the display apparatus is viewed from the front is set as a zero viewing angle (a viewing angle of about 0°), a luminance of the light emitted from the first light emitting diode ED1 and the second light emitting diode ED2 and transmitted through the lens 140 at the zero viewing angle is less than a luminance of the light emitted from the first light emitting diode ED1 and the second light emitting diode ED2 and transmitted through the lens 140 at non-zero viewing angles.

For example, the display apparatus 1000 according to one or more embodiments of the present disclosure may further include a touch insulating layer disposed on the encapsulation layer 120, a bridge electrode disposed on the touch insulating layer, a touch interlayer insulating layer covering the bridge electrode, a plurality of touch electrodes disposed on the touch interlayer insulating layer, and a touch protection layer covering the plurality of touch electrodes. For example, the second barrier layer 132 may be disposed on the same layer as the touch electrodes and may be made of the same material, but is not limited thereto.

The lens protection layer 150 may be a planarization film covering the plurality of lenses 140 and the second barrier layer 132.

The lens protection layer 150 may be formed of a material having a refractive index lower than that of the lens 140 so that light refracted in a specific direction on the surface of the lens 140 proceeds in the originally set direction. For example, the lens protection layer 150 may be formed of oil having a low refractive index, but is not limited thereto. For example, the lens protection layer 150 may include an organic insulating material having a refractive index lower than that of the lens 140.

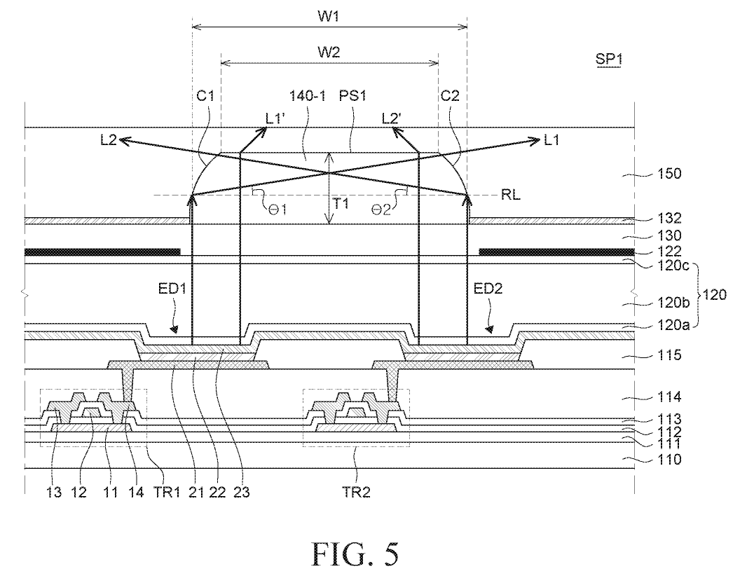

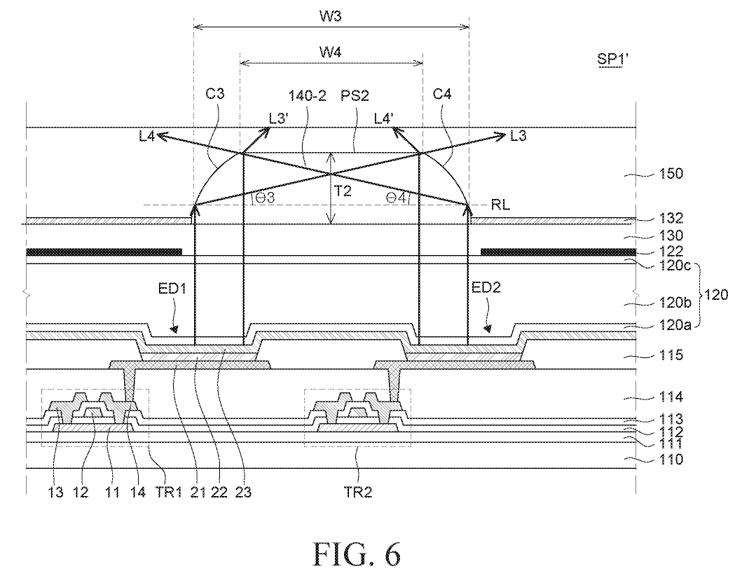

Hereinafter, referring to FIGS. 5 and 6, detailed description will be made on the structures of the lenses 140 according to one or more embodiments of the present disclosure and methods of controlling optical paths.

FIG. 5 is a cross-sectional view illustrating a first example of a lens of a display apparatus according to one or more embodiments of the present disclosure.

FIG. 6 is a cross-sectional view illustrating a second example of a lens of a display apparatus according to one or more embodiments of the present disclosure.

In FIG. 5, a lens 140-1 according to the first example included in the display apparatus 1000 according to one or more embodiments of the present disclosure is illustrated. In addition, in FIG. 5, a cross-sectional view of any one sub pixel SP1 area in which the lens 140-1 according to the first example is disposed is described as an example.

The lens 140-1 is designed such that the width W1 of its bottom surface is 31 μm, the height T1 from the bottom surface to the top surface PS1 is 14 μm, and the width W2 of the flat top surface PS1 is 10 μm.

Referring to FIG. 5, light L1 emitted from a portion (for example, the central portion of the first light emitting diode ED1 in FIG. 5) of the emission area of the first light emitting diode ED1 is incident on one side surface (for example, the left side surface C1 in FIG. 5) of the lens 140-1, and is refracted on the surface of one side surface of the lens 140-1 toward the right direction which is the second viewing direction.

In addition, light L1′ emitted from another portion (for example, an edge adjacent to the bank 115 between the first light emitting diode ED1 and the second light emitting diode ED2 in FIG. 5) of the emission area of the first light emitting diode ED1 is incident on one point of the top surface PS1 of the lens 140-1, and is refracted on the surface of the top surface PS1 of the lens 140-1 toward the right direction which is the second viewing direction. At this time, the refraction angle of light L1 refracted at side surface C1 of the lens 140-1 is different from the refraction angle of light L1′ refracted at the top surface PS1. For example, the refraction angle of light L1′ refracted at the top surface PS1 of the lens 140-1 may be larger than the refraction angle of light L1 refracted at the side surface C1.

In addition, light L2 emitted from a portion (for example, the central portion of the second light emitting diode ED2 in FIG. 5) of the emission area of the second light emitting diode ED2 is incident on the other side surface (for example, the right side surface C2 in FIG. 5) of the lens 140-1, and is refracted on the surface of the other side surface of the lens 140-1 toward the left direction which is the first viewing direction.

In addition, light L2′ emitted from another portion (for example, an edge adjacent to the bank 115 between the first light emitting diode ED1 and the second light emitting diode ED2 in FIG. 5) of the emission area of the second light emitting diode ED2 is incident on another point of the top surface PS1 of the lens 140-1, and is refracted on the surface of the top surface PS1 of the lens 140-1 toward the left direction which is the first viewing direction. At this time, the refraction angle of light L2 refracted at the side surface C2 of the lens 140-1 is different from the refraction angle of light L2′ refracted at the top surface PS1. For example, the refraction angle of light L2′ refracted at the top surface PS1 of the lens 140-1 may be larger than the refraction angle of light L2 refracted at the side surface C2.

In FIG. 6, a lens 140-2 according to the second example included in the display apparatus 1000 according to one or more embodiments of the present disclosure is illustrated. In addition, in FIG. 6, a cross-sectional view of any one sub pixel SP1’ area in which the lens 140-2 according to the second example is disposed is described as an example.

The lens 140-2 is designed such that the width W3 of its bottom surface is 31 μm, the height T2 from the bottom surface to the top surface PS2 is 14 μm, and the width W4 of the flat top surface PS2 is 8 μm. The lens 140-2 has the same width of the bottom surface and the same height from the bottom surface to the top surface as the lens 140-1, but is designed such that the width of the flat top surface is smaller. In addition, both side surfaces C1 and C2 of the lens 140-1 are designed to have a lower curvature than both side surfaces C3 and C4 of the lens 140-2.

Referring to FIG. 6, light L3 emitted from a portion (for example, the central portion of the first light emitting diode ED1 in FIG. 6) of the emission area of the first light emitting diode ED1 is incident on one side surface (for example, the left side surface C3 in FIG. 6) of the lens 140-2, and is refracted on the surface of the one side surface of the lens 140-2 toward the right direction which is the second viewing direction.

In addition, light L3′ emitted from another portion (for example, an edge adjacent to the bank 115 between the first light emitting diode ED1 and the second light emitting diode ED2 in FIG. 6) of the emission area of the first light emitting diode ED1 is incident on one point of the top surface PS2 of the lens 140-2, and is refracted on the surface of the top surface PS2 of lens 140-2 toward the right direction which is the second viewing direction. At this time, the refraction angle of light L3 refracted at the side surface C3 of the lens 140-2 is different from the refraction angle of light L3′ refracted at the top surface PS2. For example, the refraction angle of light L3′ refracted at the top surface PS2 of the lens 140-2 may be larger than the refraction angle of light L3 refracted at the side surface C3.

In addition, light L4 emitted from a portion (for example, the central portion of second light emitting diode ED2 in FIG. 6) of the emission area of the second light emitting diode ED2 is incident on the other side surface (for example, the right side surface C4 in FIG. 6) of the lens 140-2, and is refracted on the surface of the other side surface of the lens 140-2 toward the left direction which is the first viewing direction.

In addition, light L4′ emitted from another portion (for example, an edge adjacent to the bank 115 between the first light emitting diode ED1 and the second light emitting diode ED2 in FIG. 6) of the emission area of the second light emitting diode ED2 is incident on another point of the top surface PS2 of the lens 140-2, and is refracted on the surface of the top surface PS2 of the lens 140-2 toward the left direction which is the first viewing direction. At this time, the refraction angle of light L4 refracted at the side surface C4 of the lens 140-2 is different from the refraction angle of light L4′ refracted at the top surface PS2. For example, the refraction angle of light L4′ refracted at the top surface PS2 of the lens 140-2 may be larger than the refraction angle of light L4 refracted at the side surface C4.

As described above, the display apparatus 1000 according to one or more embodiments of the present disclosure may achieve light separation into two different main viewing directions through the lens 140-1 according to the first example or the lens 140-2 according to the second example.

In this case, the lower the curvature of the lens, the more efficiently light may be separated into different main viewing directions (for example, left and right directions), thereby securing high luminance for each main viewing direction.

In order for a lens to have a relatively low curvature, if it is assumed that the lens width is the same, the lens height needs to be increased; and if it is assumed that the lens height is the same, the lens width needs to be reduced. However, in the display apparatus 1000, the design height of the lens is limited, and when the width of the lens is reduced, the area overlapping the emission area also becomes narrower, which may cause a decrease in luminance.

Accordingly, the display apparatus 1000 according to one or more embodiments of the present disclosure may secure a degree of freedom in lens height by implementing the top surface of the lens as a flat surface, like the lens 140-1 according to the first example or the lens 140-2 according to the second example, and thus may implement the side surfaces of the lens with lower curvature.

The lenses 140-1 and 140-2 have the same width of the bottom surface and the same height, but by forming the width W2 of the top surface PS1 of the lens 140-1 wider than the width W4 of the top surface PS2 of the lens 140-2, the side surfaces C1 and C2 of the lens 140-1 may be implemented with lower curvature than both the side surfaces C3 and C4 of the lens 140-2.

Referring to FIGS. 5 and 6 together, light L2 refracted toward the first viewing direction and light L1 refracted toward the second viewing direction through the lens 140-1 each have a larger refractive index than light L3 refracted toward the first viewing direction and light L4 refracted toward the second viewing direction through the lens 140-2. That is, both the side surfaces C1 and C2 of lens 140-1 have lower curvature than the both side surfaces C3 and C4 of the lens 140-2.

Specifically, as illustrated in FIG. 5, the light L1 and light L2 respectively incident from the first light emitting diode ED1 and the second light emitting diode ED2 pass through refraction points at both side surfaces C1 and C2 of the lens 140-1, and a reference line RL parallel to the bottom surface of the lens 140-1 may be defined. At this time, a refraction angle θ2 of light L2 refracted toward the first viewing direction (i.e., left direction) with respect to the reference line RL and a refraction angle θ1 of light L1 refracted toward the second viewing direction(i.e., right direction) with respect to the reference line RL may be defined.

In addition, as illustrated in FIG. 6, light L3 and light L4 respectively incident from the first light emitting diode ED1 and the second light emitting diode ED2 pass through refraction points at both side surfaces C3 and C4 of the lens 140-2, and the reference line RL parallel to the bottom surface of the lens 140-2 may be defined. At this time, a refraction angle θ4 of light L4 refracted toward the first viewing direction with respect to the reference line RL and a refraction angle θ3 of light L3 refracted toward the second viewing direction with respect to the reference line RL may be defined.

At this time, the refraction angle θ1 of the light L1 refracted through one side surface of the lens 140-1 is larger than refraction angle θ3 of the light L3 refracted through one side surface of the lens 140-2, and the refraction angle θ2 of the light L2 refracted through the other side surface of the lens 140-1 is larger than the refraction angle θ4 of the light L4 refracted through the other side surface of the lens 140-2.

Accordingly, compared with the lens 140-2, the lens 140-1 may secure higher luminance performance with respect to the main viewing directions.

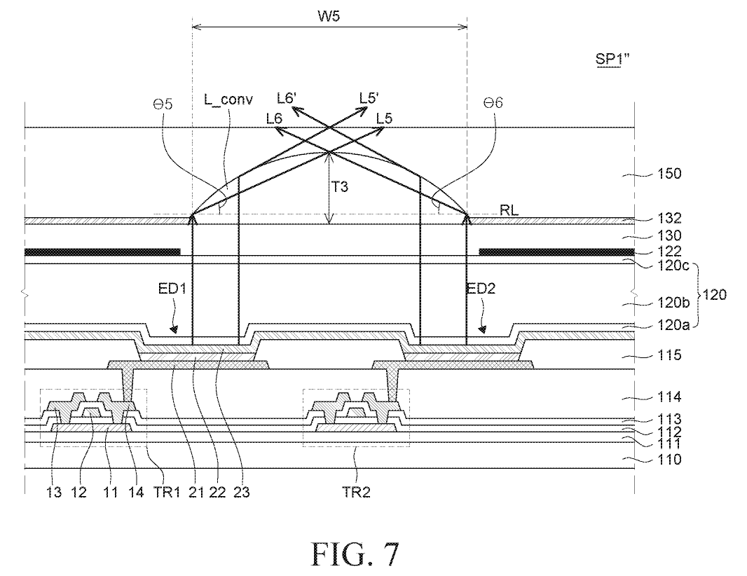

Hereinafter, referring to FIGS. 7 to 11B, the effect of light separation into the main viewing directions of the display apparatus 1000 according to one or more embodiments of the present disclosure will be described in more detail.

FIG. 7 is a cross-sectional view illustrating a structure of a lens according to a first comparative example.

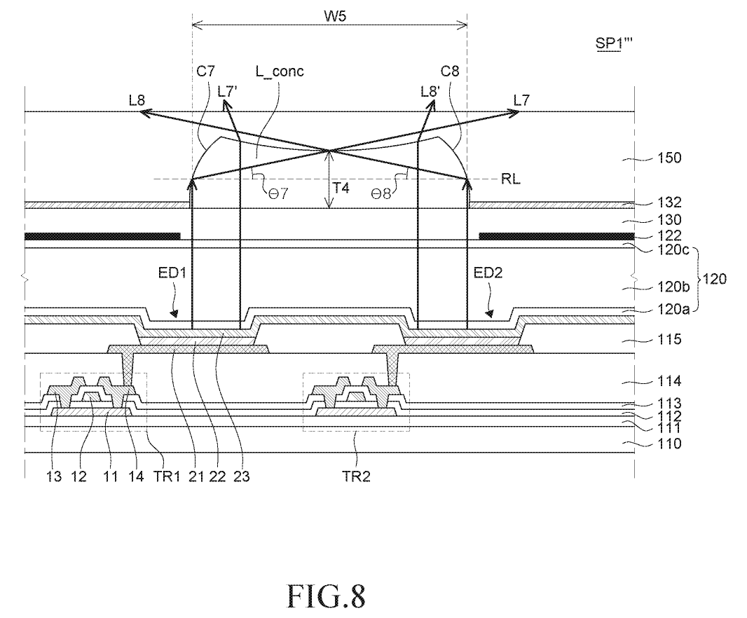

FIG. 8 is a cross-sectional view illustrating a structure of a lens according to a second comparative example.

In FIG. 7, lens L_conv according to the first comparative example is illustrated. In addition, in FIG. 7, a cross-sectional view of any one sub pixel SP1’’ area in which the lens L_conv according to the first comparative example is disposed is described as an example.

The lens L_conv is designed such that the width W5 of its bottom surface is 31 μm, the height T3 from the bottom surface to the top surface is 14 μm, and both the side surface and the top surface have curvature, thereby forming a convex lens. That is, the lens L_conv has the same width of the bottom surface and the same height as the lens 140-1 of the first example described in FIG. 5and the lens 140-2 of the second example described in FIG. 6, but is differently designed in that its top surface has a convex shape.

Referring to FIG. 7, light L5 emitted from a portion (for example, the central portion of the first light emitting diode ED1 in FIG. 7) of the emission area of the first light emitting diode ED1 is incident on one side surface (for example, the left side surface in FIG. 7) of the lens L_conv, and is refracted on the surface of one side surface of the lens L_conv toward the right direction, that is, the second viewing direction.

In addition, light L5′ emitted from another portion (for example, an edge adjacent to the bank 115 between the first light emitting diode ED1 and the second light emitting diode ED2 in FIG. 7) of the emission area of the first light emitting diode ED1 is incident on one point of the top surface of the lens L_conv, and is refracted on the top surface of the lens L_conv toward the right direction which is the second viewing direction. At this time, the refraction angle of light L5 refracted at the side surface of the lens L_conv may be different from the refraction angle of light L5′ refracted at the top surface. For example, the refraction angle of light L5′ refracted at the top surface of the lens L_conv may be larger than the refraction angle of light L5 refracted at the side surface.

In addition, light L6 emitted from a portion (for example, the central portion of the second light emitting diode ED2 in FIG. 7) of the emission area of the second light emitting diode ED2 is incident on the one side surface (for example, the right side surface in FIG. 7) of the lens L_conv, and is refracted on the surface of one side surface of the lens L_conv toward the left direction which is the first viewing direction.

In addition, light L6′ emitted from another portion (for example, an edge adjacent to the bank 115 between the first light emitting diode ED1 and the second light emitting diode ED2 in FIG. 7) of the emission area of second light emitting diode ED2 is incident on one point of the top surface of the lens L_conv, and is refracted on the top surface of the lens L_conv toward the left direction which is the first viewing direction. At this time, the refraction angle of light L6 refracted at the side surface of the lens L_conv may be different from the refraction angle of light L6′ refracted at the top surface. For example, the refraction angle of light L6′ refracted at the top surface of the lens L_conv may be larger than the refraction angle of light L6 refracted at the side surface.

Since the lens L_conv has a top surface and side surfaces both having a certain curvature, the lens L_conv cannot secure a height sufficient to implement the same side surface curvature as each of the lenses 140-1 and 140-2 described in FIGS. 5 and 6. Accordingly, the lens L_conv cannot implement the same side surface curvature as the lenses 140-1 and 140-2.

As illustrated in FIG. 7, light L5 and light L6 respectively incident from the first light emitting diode ED1 and the second light emitting diode ED2 pass through refraction points at both side surfaces of the lens L_conv, and the reference line RL parallel to the bottom surface of the lens L_conv may be defined. At this time, a refraction angle θ6 of light L6 refracted toward the first viewing direction (i.e., left direction) with respect to the reference line RL and a refraction angle θ5 of light L5 refracted toward the second viewing direction (i.e., right direction) with respect to the reference line RL may be defined. At this time, the refraction angle θ1 of light L1 refracted through one side surface of the lens 140-1 is larger than the refraction angle θ5 of light L5 refracted through one side surface of the lens L_conv, and the refraction angle θ2 of light L2 refracted through the other side surface of the lens 140-1 is larger than the refraction angle θ6 of light L6 refracted through the other side surface of the lens L_conv. In addition, the refraction angle θ3 of light L3 refracted through one side surface of the lens 140-2 is larger than the refraction angle θ5 of light L5 refracted through one side surface of the lens L_conv, and the refraction angle θ4 of light L4 refracted through the other side surface of the lens 140-2 is larger than refraction angle θ6 of light L6 refracted through the other side surface of the lens L_conv.

Accordingly, compared with the lens 140-1 and the lens 140-2, the lens L_conv exhibits lower luminance performance with respect to each of the first viewing direction and the second viewing direction.

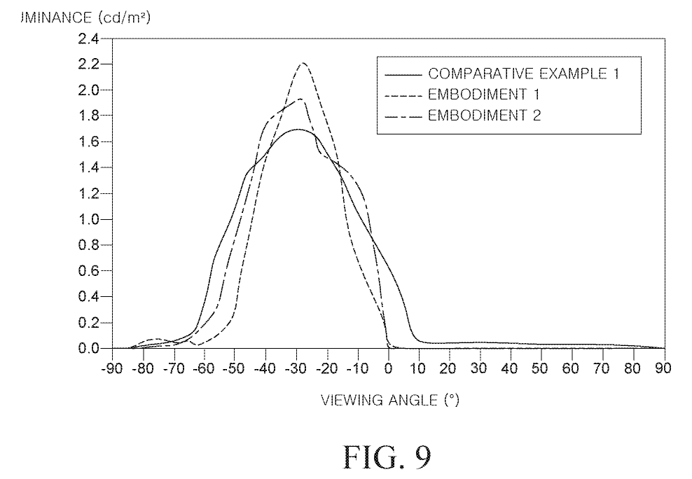

FIG. 9 is a diagram for comparing luminance profiles of the first example and the second example of a lens of a display apparatus according to one or more embodiments of the present disclosure and the first comparative example.

The graph of FIG. 9 illustrates changes in luminance value changes (i.e., luminance profiles) according to variation in viewing angle of light emitted from the first light emitting diode ED1 and the second light emitting diode ED2 and refracted through the lens. In the graph illustrated in FIG. 9, the horizontal axis corresponds to viewing angles ranging from −90° to +90°, and the vertical axis corresponds to luminance values of light emitted from the first light emitting diode ED1 and the second light emitting diode ED2 and refracted through the lens. At this time, the viewing angle when the display apparatus is viewed from the front is set as the viewing angle of 0°.

In FIG. 9, the luminance profiles of the first example and the second example of a lens of a display apparatus according to one or more embodiments of the present disclosure and the first comparative example are described as examples for the first viewing direction.

In the first example of the lens 140-1 included in the display apparatus 1000 according to one or more embodiments of the present disclosure described in FIG. 5, the design conditions are set such that the width W1 of the bottom surface is 31 μm, the height T1 from the bottom surface to the top surface PS1 is 14 μm, and the width W2 of the flat top surface PS1 is 10 μm.

In the second example of the lens 140-2 included in the display apparatus 1000 according to one or more embodiments of the present disclosure described in FIG. 6, the design conditions are set such that the width W3 of the bottom surface is 31 μm, the height T2 from the bottom surface to the top surface PS2 is 14 μm, and the width W4 of the flat top surface PS2 is 8 μm.

In addition, in the design conditions of the lens L_conv according to the first comparative example described in FIG. 7, the width W5 of the bottom surface is 31 μm, the height T3 from the bottom surface to the top surface is 14 μm, and both the side surfaces and the top surface have curvature, thereby forming a convex lens.

As described above, under the same conditions of lens height and bottom surface width, a comparison is made between luminance peak values according to viewing angle of the lens 140-1 of the first example and the lens 140-2 of the second example of the display apparatus 1000 according to one or more embodiments of the present disclosure having flat top surfaces, and the lens L_conv according to the first comparative example having a convex top surface and higher side surface curvature.

Referring to FIG. 9, the luminance peak value in the first viewing direction corresponding to the lens 140-1 of the first example included in the display apparatus 1000 according to one or more embodiments of the present disclosure (i.e., EMBODIMENT 1 in FIG. 9) is about 2.2 cd/m². The luminance peak value in the first viewing direction corresponding to the lens 140-2 of the second example included in the display apparatus 1000 according to one or more embodiments of the present disclosure (i.e., EMBODIMENT 2 in FIG. 9) is about 1.93 cd/m². In addition, the luminance peak value in the first viewing direction corresponding to the lens L_conv according to the first comparative example (i.e., COMPARATIVE EXAMPLE 1 in FIG. 9) is about 1.69 cd/m².

Thus, in a condition where the height and width of the bottom surface of the lens are the same, it can be recognized that the lens 140-2 of the second example of the display apparatus 1000 according to one or more embodiments of the present disclosure, which has a flat top surface and relatively lower side surface curvature, provides an effect in which peak luminance increases by about 14% compared with the lens L_conv accordign to the first comparative example having a convex top surface and a highter side surface curvature. In addition, in a condition where the height and width of the bottom surface of the lens are the same, it can be recognized that the lens 140-1 of the first example of the display apparatus 1000 according to one or more embodiments of the present disclosure, which has a flat top surface and relatively lowest side surface curvature, provides an effect in which peak luminance is further increased by about 14% compared with the lens 140-2 of the second example included in the display apparatus 1000 according to one or more embodiments of the present disclosure.

In FIG. 8, lens L_conc according to the second comparative example is illustrated. In addition, in FIG. 8, a cross-sectional view of any one sub pixel SP1’’’ area in which the lens L_conc according to the second comparative example is disposed is described as an example.

The lens L_conc is designed such that the width W5 of its bottom surface is 31 μm, the height T4 from the bottom surface to the center point of the top surface is 10 μm, the height from the bottom surface to the edge points of the top surface is 14 μm, the width between both edge points of the top surface is 12 μm, and both the side surfaces and the top surface have curvature, thereby forming a concave lens. That is, the lens L_conc has the same width of the bottom surface as the lens 140-1 of the first example described in FIG. 5 and the lens 140-2 of the second example described in FIG. 6, but is differently designed in that its top surface has a concave shape.

Referring to FIG. 8, light L7 emitted from a portion (for example, the central portion of the first light emitting diode ED1 in FIG. 8) of the emission area of the first light emitting diode ED1 is incident on one side surface (for example, the left side surface C7 in FIG. 8) of the lens L_conc, and is refracted on the surface of the one side surface of the lens L_conc toward the right direction which is the second viewing direction.

In addition, light L7′ emitted from another portion (for example, an edge adjacent to the bank 115 between the first light emitting diode ED1 and the second light emitting diode ED2 in FIG. 8) of the emission area of the first light emitting diode ED1 is incident on one point of the concave top surface of the lens L_conc, and is refracted on the top surface of the lens L_conc not toward the second viewing direction but toward the first viewing direction (i.e., left direction) according to the characteristic of the concave lens. At this time, the refraction angle of light L7 refracted at the side surface of lens L_conc may be different from the refraction angle of light L7′ refracted at the top surface. For example, the refraction angle of light L7′ refracted at the top surface of lens L_conc may be larger than the refraction angle of light L7 refracted at the side surface.

In addition, light L8 emitted from a portion (for example, the central portion of the second light emitting diode ED2 in FIG. 8) of the emission area of the second light emitting diode ED2 is incident on the other side surface (for example, the right side surface C8 in FIG. 8) of the lens L_conc, and is refracted on the surface of the other side surface of the lens L_conc toward the left direction which is the first viewing direction.

In addition, light L8′ emitted from another portion (for example, an edge adjacent to the bank 115 between the first light emitting diode ED1 and the second light emitting diode ED2 in FIG. 8) of the emission area of the second light emitting diode ED2 is incident on one point of the concave top surface of the lens L_conc, and is refracted on the top surface of the lens L_conc not toward the first viewing direction but toward the second viewing direction (i.e., right direction) according to the characteristic of the concave lens. At this time, the refraction angle of light L8 refracted at the side surface of the lens L_conc may be different from the refraction angle of light L8′ refracted at the top surface. For example, the refraction angle of light L8′ refracted at the top surface of the lens L_conc may be larger than the refraction angle of light L8 refracted at the side surface.

Since the lens L_conc has a top surface with a certain curvature but a concave shape, a height to implement the same side surface curvature as the lens 140-1 of the first example described in FIG. 5 or the lens 140-2 of the second example described in FIG. 6 may be secured.

As illustrated in FIG. 8, light L7 and light L8 respectively incident from the first light emitting diode ED1 and the second light emitting diode ED2 pass through refraction points at both side surfaces of the lens L_conc, and the reference line RL parallel to the bottom surface of the lens L_conc may be defined. At this time, a refraction angle θ8 of light L8 refracted toward the first viewing direction (i.e., left direction) with respect to the reference line RL and a refraction angle θ7 of light L7 refracted toward the second viewing direction (i.e., right direction) with respect to the reference line RL may be defined.

In this case, when the width between both edge points of the top surface of the lens L_conc is designed to be the same as the width W2 of top surface PS1 of the lens 140-1, the refraction angle θ1 of light L1 refracted through one side surface of the lens 140-1 and the refraction angle θ7 of light L7 refracted through one side surface of the lens L_conc may be the same, and the refraction angle θ2 of light L2 refracted through the other side surface of the lens 140-1 and the refraction angle θ8 of light L8 refracted through the other side surface of the lens L_conc may be the same. Likewise, when the width between both edge points of the top surface of the lens L_conc is designed to be the same as the width W4 of top surface PS2 of the lens 140-2, the refraction angle θ3 of light L3 refracted through one side surface of the lens 140-2 and the refraction angle θ7 of light L7 refracted through one side surface of the lens L_conc may be the same, and the refraction angle θ4 of light L4 refracted through the other side surface of the lens 140-2 and the refraction angle θ8 of light L8 refracted through the other side surface of the lens L_conc may be the same.

However, since light reflected through the concave top surface of the lens L_conc is scattered in a direction other than the main viewing direction guided by each light emitting diode, the lens L_conc exhibits lower luminance performance with respect to the first viewing direction and the second viewing direction compared with the lens 140-1 and the lens 140-2.

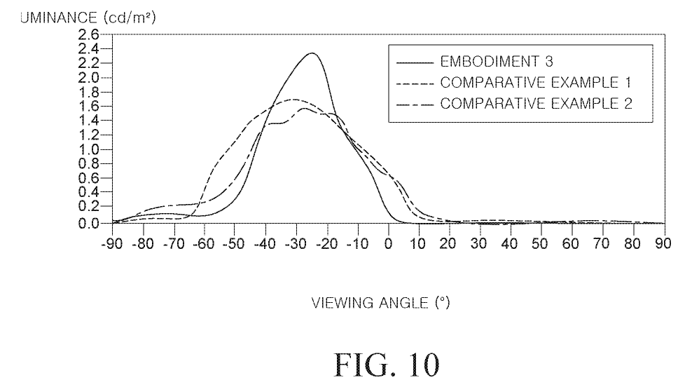

FIG. 10 is a diagram for comparing luminance profiles of the third example of a lens of a display apparatus according to one or more embodiments of the present disclosure and the first comparative example and the second comparative example.

In the graph illustrated in FIG. 10, the horizontal axis corresponds to viewing angles ranging from −90° to +90°, and the vertical axis corresponds to luminance values of light emitted from the first light emitting diode ED1 and the second light emitting diode ED2 and refracted through the lens. At this time, the viewing angle when the display apparatus is viewed from the front is set as the viewing angle of 0°.

In FIG. 10, the luminance profiles of the third example of a lens of a display apparatus according to one or more embodiments of the present disclosure, the first comparative example, and the second comparative example are described as examples for the first viewing direction.

The lens according to the third example of the display apparatus according to one or more embodiments of the present disclosure described in FIG. 10 is designed to have both side surfaces with curvature and a flat top surface, as in the lenses 140-1 and 140-2 described in FIGS. 5 and 6. That is, in the design conditions of the lens according to the third example of the display apparatus according to one or more embodiments of the present disclosure described in FIG. 10, the width of the bottom surface is 31 μm, and the height from the bottom surface to the top surface is 14 μm. In addition, the lens according to the third example of the display apparatus according to one or more embodiments of the present disclosure described in FIG. 10 is designed under the same conditions of the width of the bottom surface and the height from the bottom surface to the top surface as lens 140-1 and lens 140-2. However, the lens according to the third example of the display apparatus according to one or more embodiments of the present disclosure described in FIG. 10 is designed such that the width of the flat top surface is 12 μm and the curvature of both side surfaces is lower than that of each side surface of lens 140-1 and lens 140-2.

In addition, in the design conditions of the lens L_conv according to the first comparative example described in FIG. 7, the width W5 of the bottom surface is 31 μm, the height T3 from the bottom surface to the center point of the top surface is 14 μm, and both the side surfaces and the top surface of the lens L_conv have curvature, thereby forming a convex lens.

In addition, in the design conditions of the lens L_conc according to the second comparative example described in FIG. 8, the width W5 of the bottom surface is 31 μm, the height T4 from the bottom surface to the center point of the top surface is 10 μm, the height from the bottom surface to the edge points of the top surface is 14 μm, the width between both edge points of the top surface of the lens L_conc is 12 μm, and both the side surfaces and the top surface of the lens L_conc have curvature, thereby forming a concave lens.

As described above, under the same conditions of height and width of bottom surface of the lenses, a comparison is made among luminance peak values according to viewing angle of the lens according to the third example of the display apparatus 1000 according to one or more embodiments of the present disclosure having a flat top surface, the convex lens L_conv according to the first comparative example having high side surface curvature, and the concave lens L_conc according to the second comparative example in which light is scattered.

Referring to FIG. 10, the luminance peak value in the first viewing direction corresponding to the lens of the third example of the display apparatus 1000 according to one or more embodiments of the present disclosure (i.e., EMBODIMENT 3 in FIG. 10) is about 2.32 cd/m². The luminance peak value in the first viewing direction corresponding to the lens L_conv according to the first comparative example (i.e., COMPARATIVE EXAMPLE 1 in FIG. 10) is about 1.69 cd/m². In addition, the luminance peak value in the first viewing direction corresponding to the lens L_conc according to the second comparative example (i.e., COMPARATIVE EXAMPLE 2 in FIG. 10) is about 1.56 cd/m².

Thus, under the same conditions of the height of the lens and the width of the bottom surface of the lens, the lens of the third example of the display apparatus 1000 according to one or more embodiments of the present disclosure having a flat top surface provides an effect of about 37% increase in peak luminance compared to convex lens L_conv according to the first comparative example having high side surface curvature. In addition, under the same conditions of the width of the bottom surface and the width of the top surface of the lens, the lens of the third example of the display apparatus 1000 according to one or more embodiments of the present disclosure having a flat top surface provides an effect of about 48% increase in peak luminance compared to concave lens L_conc according to the second comparative example in which light is scattered.

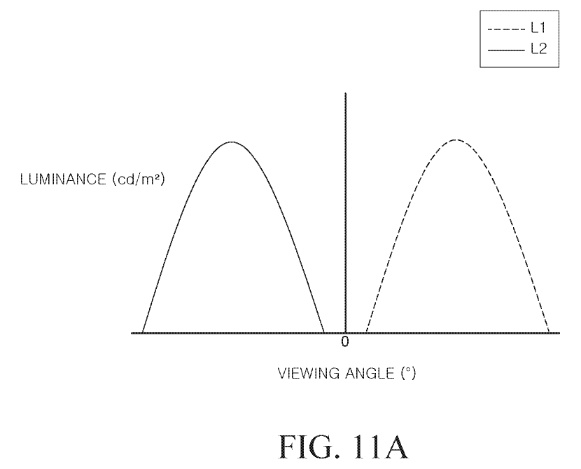

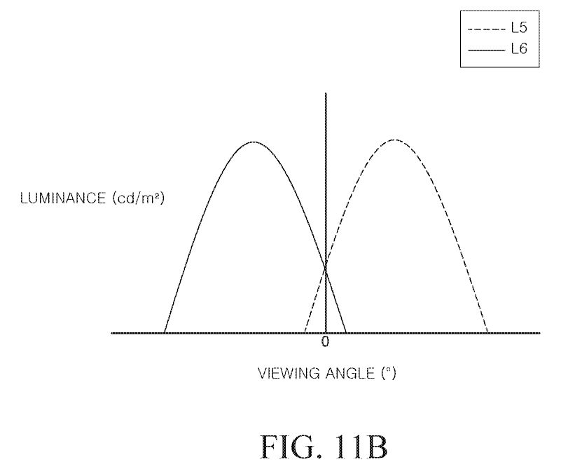

FIG. 11A is a diagram illustrating luminance profiles in two main viewing directions through a lens of a display apparatus according to one or more embodiments of the present disclosure.

FIG. 11B is a diagram illustrating luminance profiles in two main viewing directions through a lens according to the first comparative example.

In each of FIGS. 11A and 11B, the horizontal axis corresponds to viewing angles ranging from −90° to +90°, and the vertical axis corresponds to luminance values of light emitted from the first light emitting diode ED1 and the second light emitting diode ED2 and refracted through the lens. At this time, the viewing angle when the display apparatus is viewed from the front is set as the viewing angle of 0°.

In FIG. 11A, luminance profiles of light L1 and light L2 refracted through lens 140-1 of the display apparatus 1000 according to one or more embodiments of the present disclosure described in FIG. 5 are illustrated as examples. In addition, in FIG. 11B, luminance profiles of light L5 and light L6 refracted through lens L_conv according to the first comparative example described in FIG. 7 are illustrated as examples.

Referring to FIG. 11A, it can be recognized that light L1 incident on lens 140-1 from the first light emitting diode ED1 and refracted through one side surface C1 and a portion of the flat top surface PS1 of the lens 140-1, and light L2 incident on the lens 140-1 from the second light emitting diode ED2 and refracted through the other side surface C2 and another portion of the flat top surface PS1 of lens 140-1 have very strong light directivity toward the first viewing direction and the second viewing direction, respectively, and do not overlap each other within a certain range including 0° of viewing angle.

On the other hand, referring to FIG. 11B, it can be recognized that light L5 and light L6 incident on the lens L_conv from the first light emitting diode ED1 and the second light emitting diode ED2, and refracted through the side surface and the top surface each having curvature of the lens L_conv, have light directivity toward the first viewing direction and the second viewing direction, respectively, but overlap each other within a certain range including 0° of viewing angle.

Accordingly, the display apparatus 1000 according to one or more embodiments of the present disclosure may separate light from the light emitting diode through a lens having side surfaces of low curvature and a flat top surface, such that images directed to different main viewing directions may not overlap with each other when the viewing angle is about 0°.

For example, as described above with reference to FIG. 1, when the display apparatus 1000 according to one or more embodiments of the present disclosure is a vehicle display apparatus and is disposed on a dashboard and a center fascia between a driver’s seat and a passenger’s seat, images displayed through the display apparatus 1000 may not be recognized in a front direction between the driver’s seat and the passenger’s seat (for example, the rear seat direction). Accordingly, while high luminance may be secured for images displayed in different main viewing directions, recognition of images in directions other than the main viewing directions may be suppressed, thereby protecting privacy of images displayed in the main viewing directions.

The embodiments of the present disclosure can also be described as follows:

According to one or more embodiments of the present disclosure, there is provided a display apparatus. The display apparatus includes a substrate. The display apparatus further includes a first light emitting diode and a second light emitting diode disposed on the substrate and emitting light of the same color. And the display apparatus further includes a lens disposed on the first light emitting diode and the second light emitting diode and controlling a path of light emitted from the first light emitting diode and the second light emitting diode. Both side surfaces of the lens have curvature, and a top surface of the lens is flat.

The first light emitting diode may overlap a portion of the top surface of the lens and one of the both side surfaces of the lens. The second light emitting diode may overlap another portion of the top surface of the lens and the other side surface of the both side surfaces of the lens.

The display apparatus may further include a bank defining emissive areas of the first light emitting diode and the second light emitting diode. The bank may be disposed between the first light emitting diode and the second light emitting diode and may overlap the top surface of the lens.

The display apparatus may further include: an encapsulation layer disposed on the first light emitting diode and the second light emitting diode, and a first barrier layer disposed on the encapsulation layer and disposed to enclose the lens on a plane. The first barrier layer may overlap a portion of the emissive areas of the first light emitting diode and the second light emitting diode.

The display apparatus may further include an organic insulating layer disposed on the first barrier layer and the encapsulation layer. The lens may be disposed on the organic insulating layer.

The display apparatus may further include a second barrier layer disposed on the organic insulating layer on the same plane as the lens and disposed to enclose the lens on a plane. The second barrier layer may overlap a portion of the emissive areas of the first light emitting diode and the second light emitting diode.

The second barrier layer may have a wider overlapping area with the emissive areas of the first light emitting diode and the second light emitting diode than the first barrier layer.

According to one or more embodiments of the present disclosure, there is provided a display apparatus. The display apparatus includes a substrate in which a plurality of pixels each including a plurality of sub pixels is defined. The display apparatus further includes a first light emitting diode and a second light emitting diode disposed on the substrate in each of the plurality of sub pixels. And the display apparatus further includes a lens disposed on the first light emitting diode and the second light emitting diode in each of the plurality of sub pixels, the lens controlling a path of light emitted from the first light emitting diode in a first direction, and the lens controlling a path of light emitted from the second light emitting diode in a second direction different from the first direction. Top surfaces of the plurality of lenses are flat, and both side surfaces of the plurality of lenses are curved surfaces.

The first light emitting diode and the second light emitting diode disposed in one of the plurality of sub pixels may emit light of the same color.

A portion of the top surface of the lens and one of the both side surfaces may overlap the first light emitting diode. Another portion of the top surface of the lens and the other of the both side surfaces may overlap the second light emitting diode.

The display apparatus may further include a bank defining emissive areas of the plurality of first light emitting diodes and the plurality of second light emitting diodes. The bank may overlap the top surface of the lens between the first light emitting diode and the second light emitting diode disposed in one of the plurality of sub pixels.

The display apparatus may further include: an encapsulation layer covering the plurality of first light emitting diodes and the plurality of second light emitting diodes; and a first barrier layer disposed on the encapsulation layer and disposed to enclose the plurality of lenses on a plane.

The first barrier layer may overlap a portion of the emissive areas of the first light emitting diode and the second light emitting diode.

The display apparatus may further include: an organic insulating layer disposed on the encapsulation layer and the first barrier layer; and a second barrier layer disposed on the organic insulating layer on the same plane as the plurality of lenses and disposed to enclose the plurality of lenses on a plane.

The second barrier layer may overlap a portion of the emissive areas of the first light emitting diode and the second light emitting diode.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A display apparatus, comprising:
a substrate;
a first light emitting diode and a second light emitting diode disposed on the substrate and emitting light of a same color; and
a lens disposed on the first light emitting diode and the second light emitting diode, the lens controlling a path of light emitted from the first light emitting diode and the second light emitting diode,
wherein side surfaces facing each other of the lens have curvature, and
wherein a top surface of the lens is flat.

2. The display apparatus according to claim 1, wherein the first light emitting diode overlaps a portion of the top surface of the lens and a first side surface of the side surfaces of the lens, and
wherein the second light emitting diode overlaps another portion of the top surface of the lens and a second side surface of the side surfaces of the lens.

3. The display apparatus according to claim 1, further comprising:
a bank defining emissive areas of the first light emitting diode and the second light emitting diode,
wherein the bank is disposed between the first light emitting diode and the second light emitting diode and overlaps the top surface of the lens.

4. The display apparatus according to claim 3, further comprising:
an encapsulation layer disposed on the first light emitting diode and the second light emitting diode; and
a first barrier layer disposed on the encapsulation layer, the first barrier layer enclosing the lens on a plane,
wherein the first barrier layer overlaps a first portion of the emissive areas of the first light emitting diode and the second light emitting diode.

5. The display apparatus according to claim 4, further comprising:
an organic insulating layer disposed on the first barrier layer and the encapsulation layer,
wherein the lens is disposed on the organic insulating layer.

6. The display apparatus according to claim 5, further comprising:
a second barrier layer disposed on the organic insulating layer on a same plane as the lens, the second barrier layer enclosing the lens on the plane,
wherein the second barrier layer overlaps a second portion of the emissive areas of the first light emitting diode and the second light emitting diode.

7. The display apparatus according to claim 6, wherein a second overlapping area of the second barrier layer overlapping with the second portion of the emissive areas of the first light emitting diode and the second light emitting diode is wider than a first overlapping area of the first barrier layer overlapping with the first portion of the emissive areas of the first light emitting diode and the second light emitting diode.

8. A display apparatus, comprising:
a substrate in which a plurality of pixels are disposed, each pixel of the plurality of pixels including a plurality of sub pixels;
a first light emitting diode and a second light emitting diode disposed on the substrate in each of the plurality of sub pixels; and
a lens disposed on the first light emitting diode and the second light emitting diode in each of the plurality of sub pixels, the lens controlling a path of light emitted from the first light emitting diode in a first direction, and the lens controlling a path of light emitted from the second light emitting diode in a second direction different from the first direction,
wherein a top surface of the lens is flat, and
wherein side surfaces of the lens are curved surfaces.

9. The display apparatus according to claim 8, wherein the first light emitting diode and the second light emitting diode disposed in one of the plurality of sub pixels emit light of a same color.

10. The display apparatus according to claim 8, wherein a portion of a top surface of the lens and a first side surface of the side surfaces overlap the first light emitting diode, and
wherein another portion of the top surface of the lens and a second side surface of the side surfaces overlap the second light emitting diode.

11. The display apparatus according to claim 8, further comprising:
a bank defining emissive areas of the first light emitting diode and the second light emitting diode,
wherein the bank overlaps a portion of the top surface of the lens between the first light emitting diode and the second light emitting diode disposed in one of the plurality of sub pixels.

12. The display apparatus according to claim 8, further comprising:
an encapsulation layer covering the first light emitting diode and the second light emitting diode; and
a first barrier layer disposed on the encapsulation layer, the first barrier layer enclosing the lens on a plane.

13. The display apparatus according to claim 12, wherein the first barrier layer overlaps a first portion of emissive areas of the first light emitting diode and the second light emitting diode.

14. The display apparatus according to claim 13, further comprising:
an organic insulating layer disposed on the encapsulation layer and the first barrier layer; and
a second barrier layer disposed on the organic insulating layer on a same plane as the lens, the second barrier layer enclosing the lens on the plane,
wherein the second barrier layer overlaps a second portion of the emissive areas of the first light emitting diode and the second light emitting diode.

15. A display apparatus, comprising:
a substrate; and
a first light emitting diode and a second light emitting diode disposed on the substrate, wherein the first light emitting diode and the second light emitting diode are adjacent to each other and are configured to emit light of a same color; and
a lens at least partially overlapping the first light emitting diode and the second light emitting diode, the lens including a bottom surface and a top surface opposite to the bottom surface and further from the substrate than the bottom surface, wherein at least a portion of the top surface is flat, and
wherein a luminance of the light emitted from the first light emitting diode and the second light emitting diode and transmitted through the lens at a zero viewing angle is less than a luminance of the light emitted from the first light emitting diode and the second light emitting diode and transmitted through the lens at non-zero viewing angles.

16. The display apparatus according to claim 15, wherein a first portion of the top surface of the lens overlaps a portion of the first light emitting diode, and
wherein a second portion of the top surface of the lens overlaps a portion of the second light emitting diode.

17. The display apparatus according to claim 15, wherein the lens further includes a pair of side surfaces, and
wherein at least a portion of a first side surface of the pair of side surfaces is curved,
wherein the first side surface overlaps a portion of the first light emitting diode, and
wherein a second side surface of the pair of side surfaces overlaps a portion of the second light emitting diode.

18. The display apparatus according to claim 17, further comprising:
a bank disposed on the substrate and between the first light emitting diode and the second light emitting diode,
wherein a first emission layer of the first light emitting diode that emits light is disposed in a first opening defined by the bank, the first side surface of the lens and a first portion of the top surface of the lens overlapping a portion of the first emission layer, and
wherein a second emission layer of the second light emitting diode that emits light is disposed in a second opening defined by the bank, the second side surface of the lens and a second portion of the top surface of the lens overlapping a portion of the second emission layer.

19. The display apparatus according to claim 18, further comprising:
a first barrier layer disposed on the first light emitting diode and the second light emitting diode, the first barrier layer disposed closer to the substrate than the lens is disposed, the first barrier layer including a first light absorbing material for absorbing first portions of light emitted from the first emission layer and the second emission layer,
wherein a first portion of the first barrier layer overlaps another portion of the first emission layer nonoverlapping the lens, and
wherein a second portion of the first barrier layer overlaps another portion of the second emission layer nonoverlapping with the lens.

20. The display apparatus according to claim 19, further comprising:
a second barrier layer disposed on the first barrier layer and further from the substrate than the first barrier layer is disposed, the second barrier layer including a second light absorbing material for absorbing second portions of light emitted from the first emission layer and the second emission layer, the second barrier layer in direct contact with the pair of side surfaces of the lens,
wherein a first portion of the second barrier layer in direct contact with the first side surface of the lens overlaps the first portion of the first barrier layer, and
wherein a second portion of the second barrier layer in direct contact with the second side surface of the lens overlaps the second portion of the first barrier layer.
